(19) United States
(12) Patent Application Publication
(10) Pub. No.: US 2012/0229986 A1
(43) Pub. Date: Sep. 13, 2012

(54) POWER CONVERSION SYSTEM USING FERROMAGNETIC ENCLOSURE WITH EMBEDDED WINDING TO SERVE AS MAGNETIC COMPONENT

(76) Inventor: Muzahid Bin Huda, Los Gatos, CA (US)

(21) Appl. No.: 13/411,568

(22) Filed: Mar. 4, 2012

Related U.S. Application Data
(60) Provisional application No. 61/464,780, filed on Mar. 9, 2011.

(51) Int. Cl. H05K 7/20; H01F 27/02

(52) U.S. Cl. 361/720; 336/83

(57) ABSTRACT

Unique construction methods enabling footprint and volume reduction of a power conversion system are disclosed. The embodiments of the invention allow high power densities to be achieved. The novelty of this invention is the use of a ferromagnetic enclosure as a multi-function component serving the following purposes: a) The ferromagnetic enclosure functions as the enclosure for the power converter, b) The ferromagnetic enclosure incorporates various embedded electrical winding structures, allowing it to function as one or more magnetic energy storage or magnetic coupling devices for the power converter circuit, c) The ferromagnetic enclosure allows thin, low profile magnetic storage or coupling devices to be implemented, d) The ferromagnetic enclosure functions as a thermal management device to guide heat from the power converter away from the PCB or substrate.

### CROSS REFERENCE TO RELATED APPLICATION

This application claims priority from and incorporates by reference the following U.S. Provisional Application: “Power Conversion System using Ferromagnetic Enclosure with Embedded Winding to serve as Magnetic Component”, Ser. No. 61/464,780 filed on Mar. 9, 2011.

### BACKGROUND OF THE INVENTION

### Field of the Invention

The field of the present invention pertains to electrical power conversion As power density requirements in power conversion systems continue to increase, the need for ever smaller electrical power conversion systems with more efficient thermal management is becoming more urgent.

### Description of Related Art

This disclosure describes several unique construction methods that enable overall reduction in the footprint and volume of a power conversion system. The embodiments of this invention allow high power densities (power/volume) to be achieved. The novelty of this invention is the use of a ferromagnetic enclosure for the power conversion system as a multi-function component serving the following purposes:

a) The ferromagnetic enclosure functions as the enclosure for the power converter.

b) The ferromagnetic enclosure incorporates various forms of embedded electrical winding structures, allowing it to function as one or more magnetic energy storage or magnetic coupling devices for the power converter circuit.

c) The ferromagnetic enclosure allows thin, low profile magnetic storage or coupling devices to be implemented.

d) The ferromagnetic enclosure functions as a thermal management device to guide heat from the power converter away from the PCB or substrate.

e) Compared to commonly constructed power converters with similar power ratings, this invention allows the implementation of lower profile and smaller footprint power converters.

All known electrical power conversion architectures and their possible variations can be constructed using the present invention disclosed. Such power conversion architectures include, but are not limited to buck, boost, buck-boost, flyback, forward, SEPIC, soft switching resonant converters, power factor correction circuits, and also all possible variations of these architectures. In addition to allowing power converters with higher power densities to be built, the present invention also provides a method to improve thermal management by using the ferromagnetic enclosure as a heat guide and/or thermal radiator. Information relevant to attempts at addressing these problems are found in U.S. Pat. No. 7,723,129 B2 issued to Sreenivasan K. Koduri and the following publication: IEEE Transactions on Magnetics, Vol 39, No. 5, September 2003, published by Zenchi Hayashi et. al.

### SUMMARY OF THE INVENTION

This invention disclosure describes the construction of a complete or partial power conversion system (FIG. 1) using a ferromagnetic enclosure that also doubles as the magnetic storage (inductor or choke) or magnetic conversion (transformer) device. Another function of the ferromagnetic enclosure is that of a heat sink to guide heat away from the power conversion system. The heat may be radiated directly by the ferromagnetic enclosure, or it may be radiated via heat sinks attached to any of the enclosure's surfaces.

Three different embodiments of the ferromagnetic enclosure with embedded windings serving as the magnetic component for the power conversion system are disclosed:

1) Ferromagnetic enclosure with embedded winding or windings with the ferromagnetic core completely surrounding the power converter's components as well as the PCB or substrate.

2) Ferromagnetic enclosure with embedded winding or windings in two portions (top and bottom portions).

3) A single, top or bottom ferromagnetic enclosure with embedded winding or windings.

In addition to the above, three embodiments of the construction of a power conversion system using the ferromagnetic enclosure are disclosed. The present invention and its various embodiments disclosed can be used to implement all known forms of power converter, inverter and electrical power processing systems that use magnetic energy storage (inductors) and/or magnetic voltage/current transformation and coupling (transformers) for their operation. Examples of such systems include, but are not limited to the following:

Point of Load Regulators (POL), isolated and non-isolated DC/DC converters, LED drivers, inverters, AC/DC converters, battery chargers, solar power converters, DC/AC inverters, DC converters for Power Over Ethernet (POE), voltage and current transformers, choke coils and inductors.

### BRIEF DESCRIPTION OF THE DRAWINGS

FIG. 1 illustrates the concept of the invention. It shows the conceptual implementation of one embodiment of a fully assembled power conversion system or sub-system. Item 101 is the ferromagnetic enclosure encapsulating the power conversion system. Item 102 shows one embodiment of the electrical windings embedded in the ferromagnetic enclosure to form the functional inductor, transformer or inductor-transformer combination. Item 103 shows the cavity inside the ferromagnetic enclosure. Item 104 shows electrical connections for connection to an external system. To illustrate the internal details of the construction in the following figures, a cross section cut is taken along the dashed line AA′.

FIG. 2A, FIG. 2B and FIG. 2C show three embodiments of the present invention.

FIG. 2A shows the cross section of the power conversion system encapsulated with the ferromagnetic enclosure. Item 201 is the continuous ferromagnetic enclosure. Item 202 shows the windings that form the inductor and/or transformer. Item 203 is the cavity inside the ferromagnetic enclosure. Item 204 shows components mounted on both surfaces of the Printed circuit Board (PCB) or substrate, item 205.

FIG. 2B shows the cut-away cross section of the power conversion system enclosed by two ferromagnetic half-enclosures (Items 201 and 206). Items 202 and 207 are conductors forming embedded windings. Items 203 and 208 are gaps. Items 204 and 209 are components mounted on the PCB or substrate (Item 205). Items 210 are components, connections and/or connectors mounted on Item 205.

FIG. 2C shows the cross section cut out of a power conversion system enclosed by one ferromagnetic half-enclosure (Item 201). This embodiment is a variation of that shown in FIG. 2B. As in FIG. 2B, item 202 is the conductive winding that forms the inductor and/or transformer of the power conversion system. All other items depicted in

FIG. 2C are similar to those described in FIG. 2B.

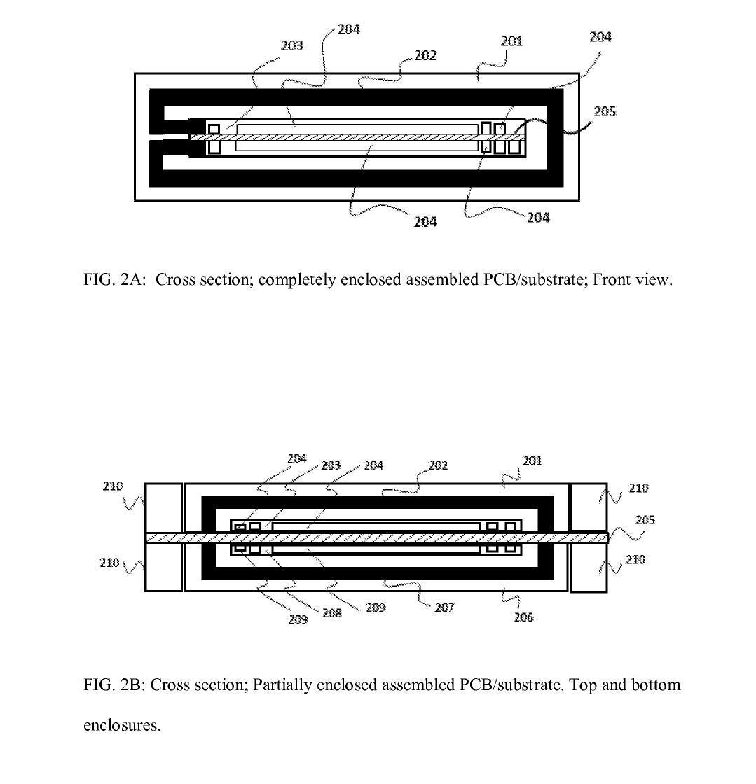

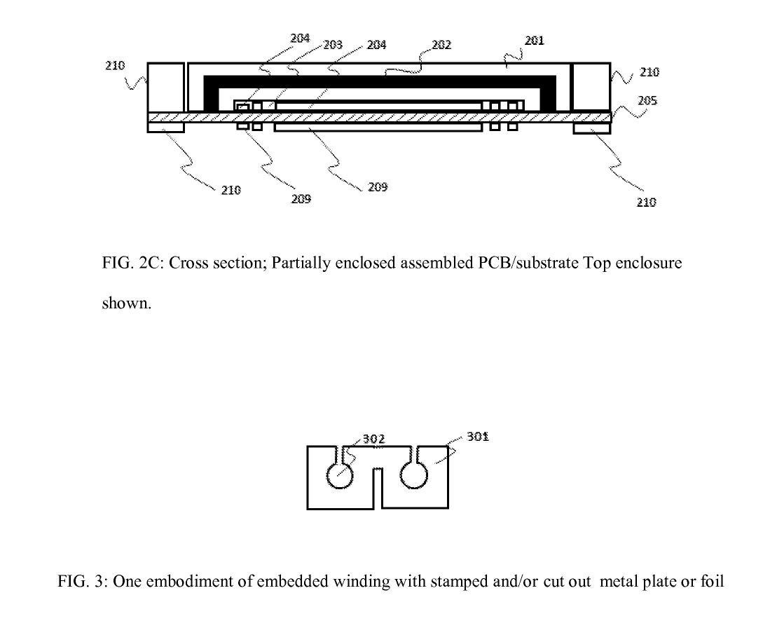

An example of one embodiment of the embedded winding used in the structures shown in FIG. 2A, FIG. 2B and FIG. 2C is shown in FIG. 3. The embedded winding consists of stamped and/or cut out pieces of a conductive plate or foil. Item 301 shows the shape of the conductive material. Item 302 is a stamped out or cut out area.

### DETAILED DESCRIPTION

Three embodiments of the ferromagnetic enclosure for encapsulating a power conversion system are described in this disclosure. The construction and embodiment of power conversion systems or sub-systems using these embodiments of the ferromagnetic enclosure are also described:

1) Ferromagnetic enclosure with embedded winding or windings with the ferromagnetic core completely surrounding the power converter's components as well as the PCB or substrate. The ferromagnetic enclosure is built as a continuous enclosure that completely encloses the power converter circuit and its PCB or substrate.

2) Ferromagnetic enclosure with embedded winding or windings in two parts (top and bottom parts). The two (top and bottom) ferromagnetic enclosures with embedded winding or windings may or may not be identical in form or function. The two ferromagnetic enclosures may completely or partially cover all the components of the power conversion system or sub-system and its PCB or substrate.

3) A single, top or bottom ferromagnetic enclosure with embedded winding or windings. Either the top or bottom surface of the power conversion system's components and PCB or substrate is not encapsulated by the ferromagnetic enclosure.

In the embodiments described, the ferromagnetic enclosure has arbitrary cross sectional and structural shapes, area and volume. Examples of cross sectional shapes for the enclosure include, but are not limited to rectangular-cylindrical, circular-cylindrical, oval-cylindrical, triangular-cylindrical, etc. Examples of the structural shape include, but are not limited to rectangular, L-shaped, flat circular, spherical, etc.

Three embodiments of the construction of a power conversion system or sub-system using the ferromagnetic enclosure are disclosed.

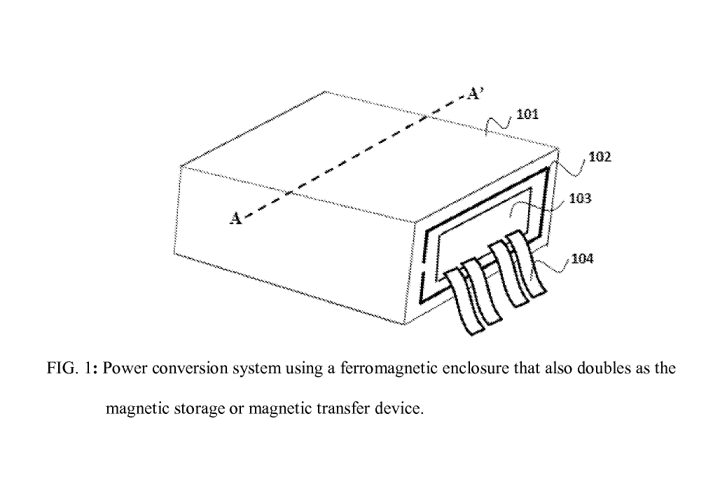

FIG. 1 shows the concept of the present invention. It shows a conceptual implementation of a fully assembled power conversion system or sub-system. Other embodiments of this concept may also be implemented. Item 101 shows the ferromagnetic enclosure for the power conversion system. It is used as an encapsulation method for the power conversion circuit. The ferromagnetic enclosure also functions as one or more inductor, transformer, or combination of inductor-transformer structures. Item 102 shows one possible embodiment of the electrical windings embedded in the ferromagnetic enclosure to form the functional inductor, transformer or inductor-transformer combination. Item 103 shows the cavity inside the ferromagnetic enclosure in which either the complete or fully assembled power conversion circuit on a PCB or substrate is housed. Item 104 shows electrical connections to the partial or complete power conversion system extended outside for connection to an external system. The electrical connections may be implemented as wires, pins, studs, metal blocks or other shapes with various conductive materials.

FIG. 2A, FIG. 2B and FIG. 2C illustrate three embodiments of the ferromagnetic enclosure and the construction of the power conversion system or subsystem. Other embodiments of the ferromagnetic enclosure and the power conversion system or sub-system are also possible.

FIG. 2A shows the cut-away cross section of the power conversion system encapsulated with the ferromagnetic enclosure. Item 201 is the continuous ferromagnetic enclosure. Item 202 shows the windings that form the inductor and/or transformer of the power conversion system embedded inside the ferromagnetic enclosure and wrapped in helical fashion along the length of the enclosure. Item 203 is the cavity inside the ferromagnetic enclosure. Item 204 shows components of the power conversion system mounted on both surfaces of the Printed circuit Board (PCB) or substrate, item 205. Mounting components on the bottom surface of item 205 is optional.

FIG. 2B shows the cut-away cross section of a second embodiment of the power conversion system enclosed by two ferromagnetic half-enclosures (Items 201 and 206). Items 202 and 207 respectively show conductive materials that form the windings of the inductor and/or transformer, embedded in each of the ferromagnetic half-enclosures 201 and 207. Items 201 and 206 are shaped in such a way that they form a cavity, or gap (Items 203 and 208). Items 204 and 209 are components of the power conversion system mounted on the two surfaces of the PCB or substrate (Item 205). The PCB may extend outside the enclosure formed by Items 201 and 206. Items 210 are components, connections and/or connectors mounted on Item 205 outside the two ferromagnetic half-enclosures.

FIG. 2C shows the cross section cut out of a partially enclosed power conversion system or sub-system enclosed by one ferromagnetic half-enclosure (Item 201). This embodiment of the power conversion system is essentially the same as that shown in FIG. 2B, but with only one of the two ferromagnetic half-enclosures used. As in FIG. 2B, item 202 is the conductive winding that forms the inductor and/or transformer of the power conversion system. Items 203 through 205, 209 and 210 in FIG. 2C are the same as described in FIG. 2B.

In one embodiment the coil windings of the inductor or magnetic coupling device (transformer) shown in FIG. 2A, FIG. 2B and FIG. 2C are completely embedded in the ferromagnetic enclosure. In a second embodiment, the coil windings of the inductor or magnetic coupling device (transformer) shown in FIG. 2A, FIG. 2B and FIG. 2C are partially embedded in the ferromagnetic enclosure.

FIG. 3 shows one embodiment of the embedded winding used in the structures described in FIG. 2A, FIG. 2B and FIG. 2C. The embedded winding may be built by stamping and/or cutting out pieces of a conductive material, and then forming and/or bending it before embedding it inside the ferromagnetic enclosure to form the inductor and/or transformer. Item 301 is the conductive material along which current flows. Item 302 is a stamped out or cut out area that forces the current in the conductor to flow pre-determined paths such as a loop. Using this embodiment of the embedded winding, an inductor or transformer is formed by embedding it inside the ferromagnetic enclosures as previously depicted in previous figures. The inductor may have any arbitrary number of turns. Various lengths and combinations (series, parallel, series-parallel) of the embedded winding with stamped metal may be used. Furthermore, various other shapes, sizes may also be formed. Multiple layers, folds are also possible and are claimed in this disclosure.

In various embodiments of the stamped or cut out inductor or transformer, the circular, oval or any other arbitrary shape are used. In yet more embodiments, any arbitrary combination of shapes are stamped or cutout to implement the embedded winding.

In various embodiments of the ferromagnetic enclosure shown in FIG. 2A one or more strands of flat wires or wires of any cross-sectional shape are used and embedded in the ferromagnetic enclosure to form the windings of the inductor or transformer. Similarly, in various embodiments of the ferromagnetic enclosure shown in FIG. 2B and FIG. 2C, one or more separate stamped or cutout conductors are embedded in the ferromagnetic enclosure to form the inductor or transformer windings.

The ferromagnetic enclosure functions as a thermal management device guiding heat away from the PCB. A key function of this enclosure is to effectively guide heat away from the system PCB on which the various embodiments of this invention may be installed as part of that system. To improve thermal radiation and cooling and micro-convection of air the ferromagnetic enclosure has the following embodiments:

In one embodiment the ferromagnetic enclosure may also has a smooth outer and inner surfaces. In a second embodiment, it has corrugated/uneven inner and outer surfaces. In a third embodiment the ferromagnetic enclosure has a combination of smooth and corrugated surfaces (Inner smooth and outer corrugated/uneven or outer smooth and inner corrugated/uneven). In yet other embodiments the inner and outer surfaces have micro-forms.

What is claimed is:

1. A ferromagnetic enclosure with embedded winding or windings functioning as an energy storage or transfer element for a power conversion system or sub-system.

2. Said enclosure of claim 1 consists of a continuous, single piece ferromagnetic structure as shown in FIG. 2A. This enclosure encapsulates a power conversion system or sub-system mounted on a substrate.

3. Said enclosure of claim 1 consists of a top and a bottom enclosure functioning as series connected, parallel connected or as two independent magnetic storage or transfer elements as shown in FIG. 2B. Said top and bottom enclosures are mounted on the substrate on which components of the power conversion system or sub-system are assembled.

4. Said enclosure of claim 1 consists of only a top or bottom piece of ferromagnetic structure as shown in FIG. 2C. Said top or bottom enclosure is mounted on the substrate on which components of the power conversion system or sub-system are assembled.

5. Said ferromagnetic enclosure of claim 1 completely or partially encloses components of a standalone power conversion system or sub-system mounted on a substrate. In another embodiment said ferromagnetic enclosure completely or partially encloses the power conversion portion of a larger system assembled on a substrate.

6. Said enclosure of claim 1 consists of either no openings, or an arbitrary number of openings of arbitrary shape and size on one or more arbitrary surfaces.

7. Any arbitrary number of electrically conducting windings embedded inside said ferromagnetic enclosure of claim 1 to form one or more inductor or transformer elements are arranged in any arbitrary number of layers, and may have any arbitrary shape, area and volume.

8. Windings of said ferromagnetic enclosure of claim 1 are constructed of metal, single or multilayer planar printed circuit board (PCB) windings or a combination of both.

9. Use of said ferromagnetic enclosure as heat guide to divert heat away from the Printed Circuit Board (PCB), substrate or other system on which the power conversion system or sub-system is constructed.

10. Voids between said ferromagnetic enclosure and said substrate are filled with thermally conductive material to improve the efficiency of heat removal from the power conversion system or sub-system.

11. The surface of the ferromagnetic enclosure is either smooth or corrugated to improve thermal radiation and convection, and also acts as a shield to prevent Electro-magnetic radiation and susceptibility.
